(19) United States
(12) Patent Application Publication
(10) Pub. No.: US 2003/0235941 A1
(43) Pub. Date: Dec. 25, 2003

(54) Method of fabricating mask ROM

(76) Inventor: Shi-Xian Chen, Hsiinchu (TW)

Correspondence Address: BIRCH STEWART KOLASCH & BIRCH, PO BOX 747, FALLS CHURCH, VA, 22040-0747, US

(21) Appl. No.: 10/301,594

(22) Filed: Nov. 22, 2002

(30) Foreign Application Priority Data
Jun. 24, 2002 (TW) 091113776

(51) Int. Cl. H01L 21/82; H01L 21/336

(52) U.S. Cl. 438/129

(57) ABSTRACT

A method of fabricating a mask read-only-memory (ROM). The method includes the steps of forming a first isolated layer on the substrate having a plurality of parallel bit lines. Next, a plurality of parallel trenches are formed on the first isolated layer to define a plurality of word lines. Then, a gate oxide layer and a polysilicon are formed on bottom of the trenches in sequence to form a plurality of parallel word lines. A second isolated layer is formed according to the topography of the substrate. The second isolated layer is etched using a plurality of parallel linear mask to form tunnel regions between the neighbored bit lines in the word lines. Finally, a coding process is programmed in selected tunnel regions using a hole patterned photoresist as a mask. According to this invention, two isolated layers are defined using the parallel linear patterned photoresist, they play as protection layers between neighbor cell regions. So that the critical dimension of photolithography is enlarged. In addition, the range of the critical dimension of the hole patterned photoresist used during coding is larger than the conventional mask, so the misalignment problem can be improved effiectvely.

### BACKGROUND OF THE INVENTION

1. Field of the Invention

The present invention relates in general to semiconductor manufacturing, and particularly to a method of fabricating a mask read-only memory (mask ROM).

2. Description of the Related Art

There will now be described a prior art process of fabricating a mask ROM with reference to the accompanying drawings, FIGS. 1A-1C.

First, a semiconductor substrate 10 having a plurality of memory cells consisting of MOS transistor is provided, as shown in FIG. 1A. A memory cell comprises a field oxide 20 formed by LOCOS, a gate layer 30, and a source/drain region 40. The orientations of gate layer and source/drain are perpendicular.

Next, as shown in FIG. 1B, a patterned photoresist layer 50 is formed by photolithography using a code mask. The memory cells which are not covered by photoresist layer 50 will be following coded into “0”. The memory cells covered by photoresist layer 50 will be subsequently coded into “1”. Then, an ion implantation 60 is performed to control threshold voltage of MOS transistor. Thereby, the coding process is achieved.

Conventionally, a hole patterned photoresist is used as a mask to implant through a substrate with a gate oxide layer, and a silicon conductive layer for defining tunnel regions during the process of fabricating a mask ROM. However, the process of fabricating a hole patterned photoresist is quite difficult for advanced technology, so the cost is high. Besides, there are a lot of difficulties in forming a hole using the photolithography technique due to random patterns with different hole sizes and forms are existed. Additionally, the critical dimension and the position of the conventional photoresist must be controlled precisely for coding, otherwise the problem of misaligment occurs.

### SUMMARY OF THE INVENTION

To solve above problem, it is an object of the present invention to provide a method of fabricating a mask ROM that avoids misalignment during coding.

It is another object of the present invention to provide a method of fabricating mask ROMs to enlarge the process window of photolithography.

The method comprises the following steps. First, a substrate having a plurality of parallel bit lines is provided. Next, a first isolated layer is formed on the substrate. The first isolated layer is then patterned to form a plurality of parallel trenches in the first isolated layer and define a plurality of word lines, wherein the bit lines and the word lines are perpendicular. A gate oxide and a gate layer are formed in the bottom of the trenches in sequence to form a plurality of word lines, wherein the height of the word lines is lower than that of the first isolated layer. A second isolated layer is formed on the surface of the entire substrate. The second isolated layer is patterned to expose the surface of the gate layer and form a plurality of tunnel regions between the neighboring bit line in the word lines. Finally, an ion implantation is performed in at least one of the tunnel regions for coding.

### BRIEF DESCRIPTION OF THE DRAWINGS

The above and other objects, features, and advantages of the present invention will become apparent from the following detailed description of preferred embodiments of the invention explained with reference to the accompanying drawings, in which:

FIGS. 1A-1C are sectional diagrams showing a prior art process of fabricating a mask ROM.

FIGS. 2A-2G are sectional diagrams showing a process of fabricating a mask ROM according to the present invention.

FIGS. 3A-3F are the top view of diagrams showing a process of fabricating a mask ROM according to the present invention.

### DETAILED DESCRIPTION OF THE INVENTION

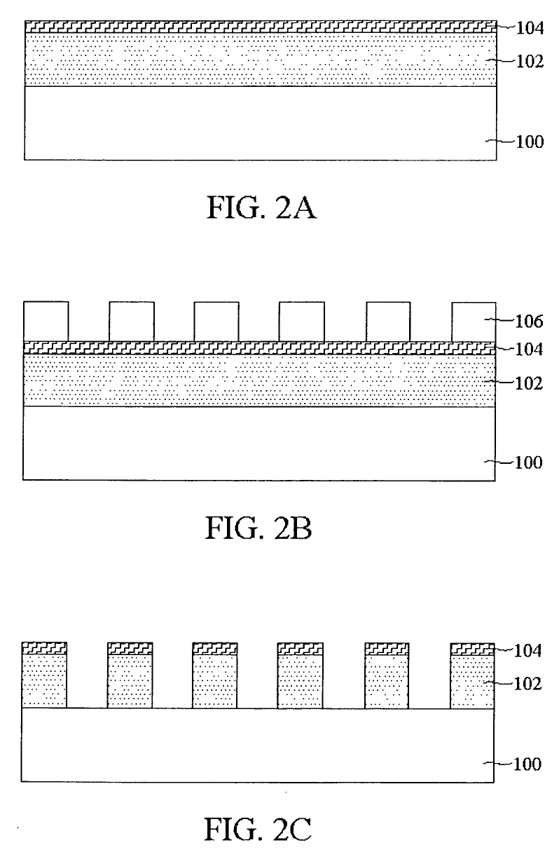

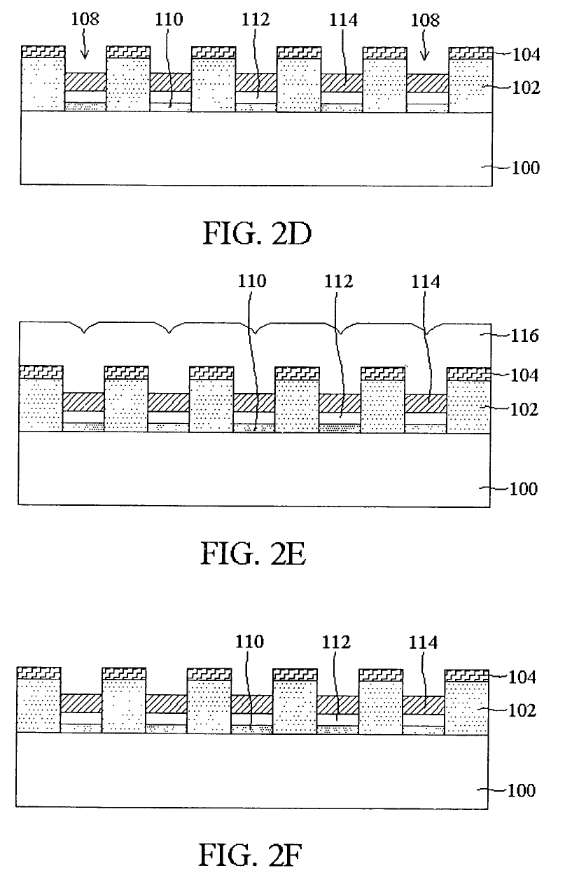

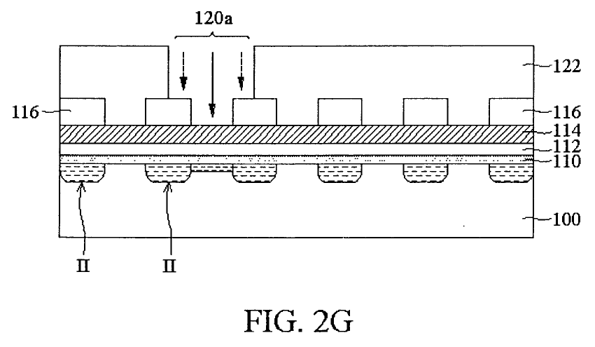

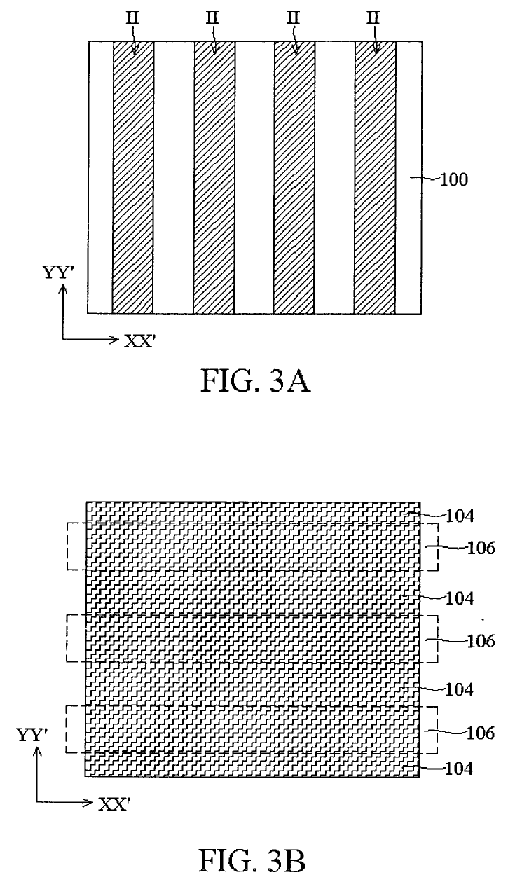

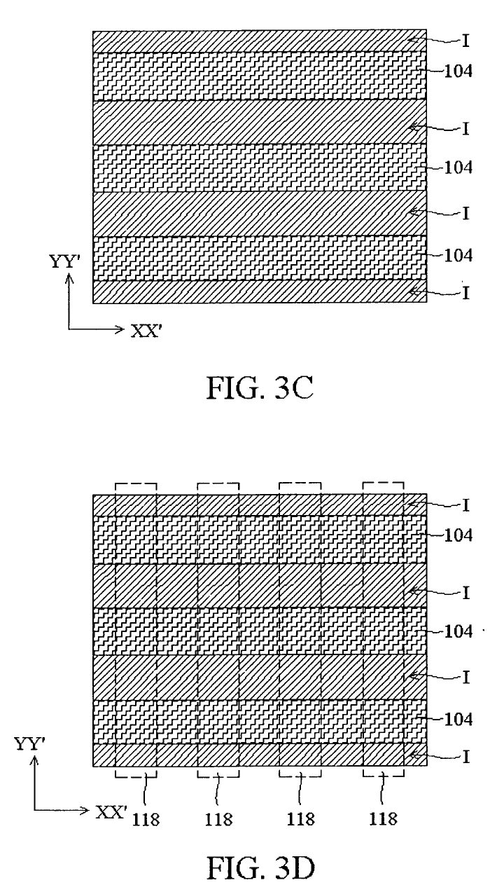

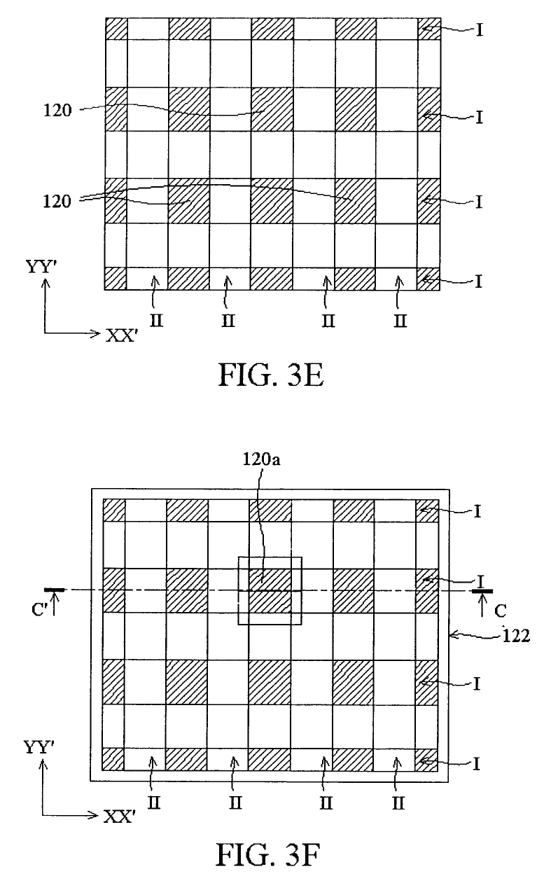

There will now be described an embodiment of this invention with reference to the accompanying drawings, FIGS. 2A-2G and FIGS. 3A-3F.

First, a substrate 100 having a plurality of parallel bit lines II is provided, as shown in FIG. 3A. The bit lines II are formed by doping.

In FIG. 2A, a first isolated layer 102 can be formed by chemical vapor deposition (CVD) on the substrate 100. The material of the isolated layer 102 comprises, for example, boro-phospho silicate glass (BPSG) or tetraethylorthosilicate (TEOS). Then, a mask layer 104 as etching stop layer is formed on the first isolated layer 102 by deposition, such as chemical vapor deposition, wherein the material of the mask layer 104 comprises SiON, for example.

In FIG. 2B, a first patterned photoresist layer 106 which is defined by a first parallel linear mask (not shown) can be formed on the substrate 100 to cover parts of the mask layer 104 by photolithography. The first patterned photoresist layer 106 and the bit lines II are perpendicular, as shown in FIG. 3B.

In FIG. 2C, an etching, such as a anisotropic dry etching, is preferably performed to etch the mask layer 104 and the first isolated layer 102 in sequence to form a plurality of parallel trenches 108 using the first patterned photoresist 106 as a mask.

In FIG. 2D, a gate oxide 110, a silicon conductive layer 112 and a conductive layer 114 are formed in the bottom of the trenches in sequence after etching. The gate oxide 110 can be formed by thermal oxidation. The silicon conductive layer 112 is preferably formed by CVD, and the material of the silicon conductive layer 112 comprises polysilicon. Then, CMP and/or etch back is performed to remove the silicon conductive layer 112 on the mask layer 104. The conductive layer 114 can be formed by salicide process. The material of the conductive layer 114 comprises titanium silicide (TiSi2) or cobalt silicide (CoSi2). Thereby, the gate oxide layer 110, the silicon conductive layer 112, and the conductive layer 114 form word lines I, as shown in FIG. 2C. The total thickness of the gate oxide layer 110, the silicon conductive layer 112, and the conductive layer 114 are controlled to make the height of the word lines I lower than the height of the mask layer 104, so that the profile of tunnel regions along the word lines I direction is defined.

In FIG. 2E, a second isolated layer 116 is formed on the entire surface substrate 100 by CVD, wherein the material of the second isolated layer 116 comprises silicon oxide, boro-phospho silicate glass (BPSG), or tetra-ethyl-ortho-silicate (TEOS).

Next, a second patterned photoresist layer 118 which is defined by a second parallel linear mask (not shown) is formed on the substrate 100 to cover parts of the second isolated layer 116 by photolithography and align the bit lines II, as shown in FIG. 3D.

In FIG. 2F, a portion of the second isolated layer 116 which is not covered by the second patterned photoresist 118 is etched until the top of the conductive layer 114 is exposed. Thereby, The tunnel regions 120 are formed between the neighbored bit lines II in the word lines I and are surrounded by two isolated layers, 116 in X-direct and 104/102 in Y-direct.

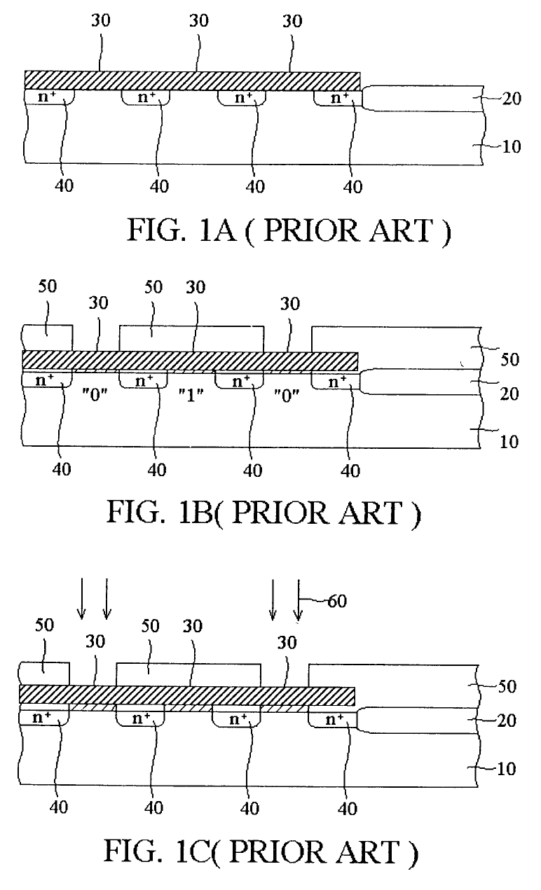

Finally, parts of the tunnel regions 120 are selected to be code regions 120a, as shown in FIG. 3F. FIG. 1G is a sectional drawing along the line cc′ in FIG. 3F. An ion implantation is performed in the code regions 120a. The range of the critical dimension of the hole patterned photoresist 122 used during coding is larger than in the prior art due to the existence of surrounding isolated layers, and the misalignment problem can be improved effectively.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method of fabricating a mask read-only-memory (ROM), comprising:
providing a substrate having a plurality of parallel bit lines;
forming a first isolated layer on the substrate;
patterning the first isolated layer to form a plurality of parallel trenches in the first isolated layer and define a plurality of word lines, wherein the bit lines and the word lines are perpendicular;
forming a gate oxide and a gate layer in the bottom of the trenches in sequence to form a plurality of word lines, wherein the height of the word lines is lower than that of the first isolated layer;
forming a second isolated layer on the surface of the entire substrate;
patterning the second isolated layer to expose the surface of the gate layer and form a plurality of tunnel regions between the neighbored bit line in the word lines; and
performing an ion implantation in at least one of the tunnel regions for coding.

2. The method as claimed in claim 1, wherein a material of the first isolated layer comprises silicon oxide.

3. The method as claimed in claim 1, further comprising the step of forming a mask layer on the first isolated layer after forming the first isolated layer.

4. The method as claimed in claim 4, wherein the mask layer is used as a stop layer during etching the second isolated layer.

5. The method as claimed in claim 1, wherein the gate oxide layer is formed by thermal oxidation.

6. The method as claimed in claim 1, wherein the gate layer comprises a polysilicon and a conductive layer.

7. The method as claimed in claim 1, the polysilicon layer is formed by chemical vapor deposition and planarized by chemical mechanical polishing or etching back.

8. The method as claimed in claim 6, wherein a material of the conductive layer comprises silicide.

9. The method as claimed in claim 8, wherein the conductive layer is formed by salicide process.

10. The method as claimed in claim 1, wherein a material of the second isolated layer comprises silicon oxide.

11. The method as claimed in claim 1, wherein the ion implantation is performed using a hole patterned photoresist as a mask.

12. The method as claimed in claim 1, wherein the pattern is defined by a plurality of parallel linear masks during the step of patterning the first isolated layer.

13. The method as claimed in claim 10, wherein the silicon-based substrate further comprises a gate oxide below the gate.

14. A method of fabricating a mask read-only-memory (ROM), comprising:
providing a substrate having a plurality of parallel bit lines;
forming a first isolated layer on the substrate;
patterning the first isolated layer to form a plurality of parallel trenches in the first isolated layer and define a plurality of word lines, wherein the bit lines and the word lines are perpendicular;
forming a gate oxide and a gate layer in the bottom of the trenches in sequence to form a plurality of word lines, wherein the height of the word lines is lower than that of the first isolated layer;
forming a second isolated layer on the surface of the entire substrate;
forming a plurality of parallel linear masks aligned the bit lines on the surface of the second isolated layer;
etching the second isolated layer using the masks until the gate layer is exposed to form a plurality of tunnel regions between the neighbored bit line in the word lines; and
performing an ion implantation in at least one of the tunnel regions for coding.

15. The method as claimed in claim 14, wherein a material of the first isolated layer comprises silicon oxide.

16. The method as claimed in claim 14, further comprising the step of forming a mask layer on the first isolated layer after forming the first isolated layer.

17. The method as claimed in claim 14, wherein the mask layer is used as a stop layer during etching the second isolated layer.

18. The method as claimed in claim 14, wherein the gate oxide layer is formed by thermal oxidation.

19. The method as claimed in claim 14, wherein the gate layer comprises a polysilicon and a conductive layer.

20. The method as claimed in claim 19, the polysilicon layer is formed by chemical vapor deposition and planarized by chemical mechanical polishing or etching back.

21. The method as claimed in claim 19, wherein a material of the conductive layer comprises silicide.

22. The method as claimed in claim 19, wherein the conductive layer is formed by salicide process.

23. The method as claimed in claim 14, wherein a material of the second isolated layer comprises silicon oxide.

24. The method as claimed in claim 14, wherein the ion implantation is performed using a hole patterned photoresist as a mask.

25. The method as claimed in claim 14, wherein the pattern is defined by a plurality of parallel linear masks during the step of patterning the first isolated layer.

26. The method as claimed in claim 14, wherein the silicon-based substrate further comprising a gate oxide below the gate.
